(19) United States
(12) Patent Application Publication
(10) Pub. No.: US 2003/0008474 A1
(43) Pub. Date: Jan. 9, 2003

(54) Method of forming shallow trench isolation

(76) Inventor: Wan-Yi Liu, Chien-Chen District (TW)

Correspondence Address: J.C. Patents, Suite 250, 4 Venture, Irvine, CA, 92618, US

(21) Appl. No.: 10/176,969

(22) Filed: Jun. 21, 2002

(30) Foreign Application Priority Data
Jun. 21, 2001 (TW) 90115051

(51) Int. Cl. H01L 21/76

(52) U.S. Cl. 438/439

(57) ABSTRACT

A method of forming a shallow trench isolation structure. A substrate is provided. A pad oxide layer and a mask layer are sequentially formed over the substrate. The substrate is patterned to form a trench in the substrate. A high-density plasma chemical vapor deposition (HDPCVD) having a high etching/deposition ratio is conducted to form an insulation layer over the substrate that also completely fills the trench. The etching/deposition ratio in the HDPCVD step is between about 0.15 and 0.6. Insulating material outside the trench region is removed. Finally, the mask layer and the pad oxide layer are sequentially removed to form a complete STI structure.

### CROSS-REFERENCE TO RELATED APPLICATION

This application claims the priority benefit of Taiwan application serial no. 90115051, filed Jun. 21, 2001.

### BACKGROUND OF THE INVENTION

1. Field of Invention

The present invention relates to an electrical insulation structure and its method of manufacture. More particularly, the present invention relates to a shallow trench isolation (STI) structure and its method of manufacture.

2. Description of Related Art

Following the rapid advance in semiconductor manufacturing technologies, the level of integration is increased. As the dimensions of each device are reduced, an electrical insulating structure such as a layer of silicon oxide formed by a local oxidation (LOCOS) is unsatisfactory. At present, the most widely adopted method for electrical isolation is shallow trench isolation (STI).

In general, the silicon oxide within an STI structure is deposited by a high-density plasma chemical vapor deposition (HDPCVD) method. The HDPCVD method is actually a process that provides two concurrent mechanisms, namely, etching and deposition. In other words, a portion of the drop-off material is simultaneously etched during deposition. Hence, the process is able to provide a high gap-filling capacity ideal for depositing silicon oxide into a shallow trench structure.

FIGS. 1A through 1D are schematic cross-sectional views showing the progression of steps for forming a shallow trench isolation (STI) structure according to a conventional method. As shown in FIG. 1A, a substrate is provided. A pad oxide layer 102 and a silicon nitride mask layer 104 are sequentially formed over the substrate 100. An anisotropic etching is conducted to remove a portion of the silicon nitride mask layer 104, the pad oxide layer 102 and the substrate 100 to form a trench 106. After the anisotropic etching, a rounded corner structure 108 is also formed near the top of the trench 106. The reason for forming the rounded corners 108 is because a sharp corner often leads to an insufficient thickness of subsequently formed gate oxide layer resulting in a leakage current. A rounded structure 108 can prevent such leakage due to an uneven gate layer thickness.

As shown in FIG. 1B, a high-density plasma chemical vapor deposition (HDPCVD) process is conducted. A silicon oxide layer 110 is formed over the entire substrate 100 and completely fills the trench 106. Although HDPCVD provides a high gap-filling capacity for silicon oxide, deposition on the trench wall near the rounded structure 108 often leads to the formation of blobs of silicon oxide that prevents the filling oxide material underneath. Consequently, a weak spot 112 is created around that region.

As shown in FIG. 1C, a chemical-mechanical polishing (CMP) of the silicon oxide layer 110 is conducted to remove a portion of the silicon oxide material outside the trench 106. The silicon nitride mask layer 104 serves as a polishing stop layer.

As shown FIG. 1D, a wet etching process is conducted to remove the silicon nitride mask layer 104 and the pad oxide layer 102 sequentially, ultimately forming an STI structure 114.

However, because each weak spot 112 is a region without silicon oxide filling, recess cavities 116 are formed at the upper corner of the trench 106 next to the substrate 100 in the final STI structure 114. Such recess cavities 116 at the corner region of an STI structure not only expose the substrate 100, but also render the exposed section of the substrate 100 vulnerable to damages in subsequent processing. In addition, the recess cavities 116 may also trap electric charges leading to a high sub-threshold leakage current in integrated devices and resulting in a lowering of threshold voltage for the gate oxide layer.

### SUMMARY OF THE INVENTION

Accordingly, one object of the present invention is to provide a method of forming a shallow trench isolation (STI) structure capable of preventing the formation of a weak spot after insulating material deposition.

A second object of this invention is to provide a method of forming a shallow trench isolation (STI) structure capable of preventing the formation of a recess cavity that exposes the substrate at the corner region of the STI structure. Thus, damages to the substrate during subsequent processing are minimized.

A third object of this invention is to provide a method of forming a shallow trench isolation (STI) structure capable of preventing the formation of a recess cavity at the corner of the STI structure so that current leakage from the cavity region is avoided.

To achieve these and other advantages and in accordance with the purpose of the invention, as embodied and broadly described herein, the invention provides a method of forming an STI structure. A substrate is provided and a pad oxide layer is formed over the substrate. A mask layer is formed over the pad oxide layer. The substrate is patterned to form a trench in the substrate. A high-density plasma chemical vapor deposition (HDPCVD) having a high etching/deposition ratio is conducted to form an insulation layer over the substrate that also completely fills the trench. The etching/deposition ratio in the HDPCVD step is between about 0.15 and 0.6. Because the HDPCVD uses a high etching/deposition ratio and has a high gap-filling capacity, insulating material is deposited on the substrate without forming any weak spots. Thereafter, insulating material outside the trench region is removed. Finally, the mask layer and the pad oxide layer are sequentially removed to form a complete STI structure.

One major aspect of this invention is the use of a high etching/deposition ratio in carrying out the HDPCVD process. A high etching/deposition ratio for a HDPCVD process has a high gap-filling capacity. Hence, insulating material can still completely fill the trench without forming any weak spots even if a rounded corner structure is present in the substrate at the upper corner region of the trench.

Since the insulation layer is free of any weak spots, a recess cavity that exposes a portion of the substrate is absent from the STI structure. Hence, damages to the exposed substrate near the recess cavity are prevented.

In addition, the absence of recess cavities around the STI structure also prevents any accumulation of electric charges in subsequent formation of a gate oxide layer. Ultimately, the source of leakage current is removed and a lowering of threshold voltage for the gate oxide layer is prevented.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIGS. 1A through 1D are schematic cross-sectional views showing the progression of steps for forming a shallow trench isolation (STI) structure according to a conventional method; and

FIGS. 2A through 2E are schematic cross-sectional views showing the progression of steps for forming a shallow trench isolation (STI) structure according to one preferred embodiment of this invention.

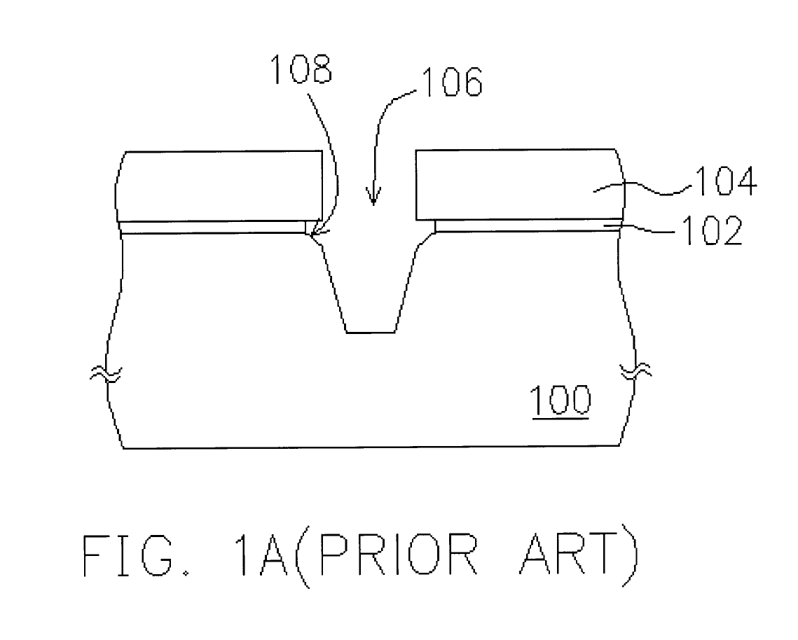

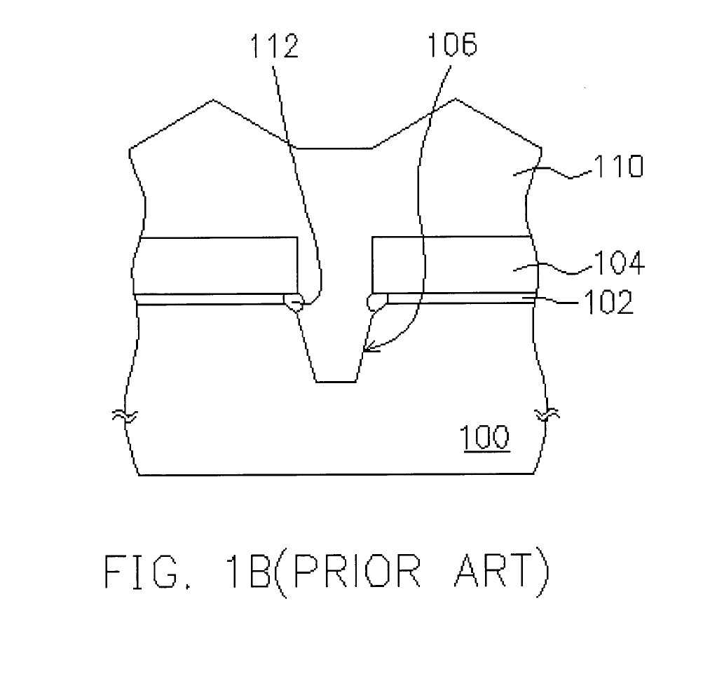

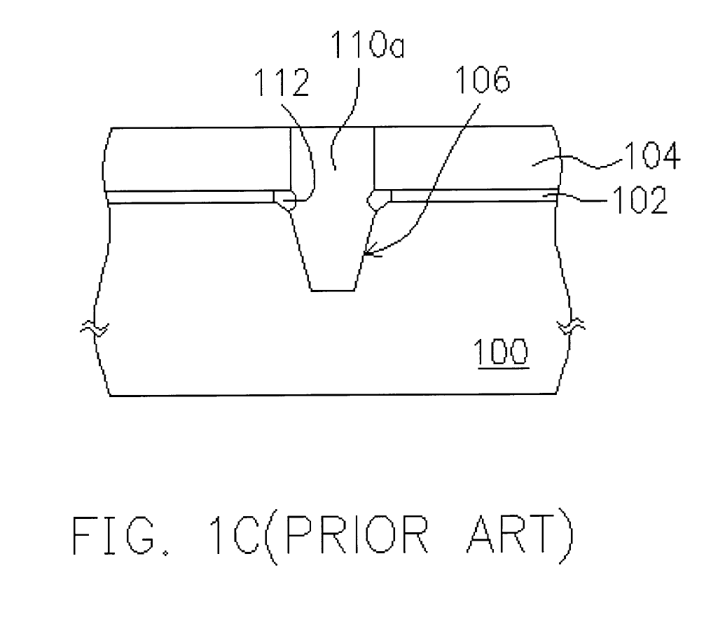

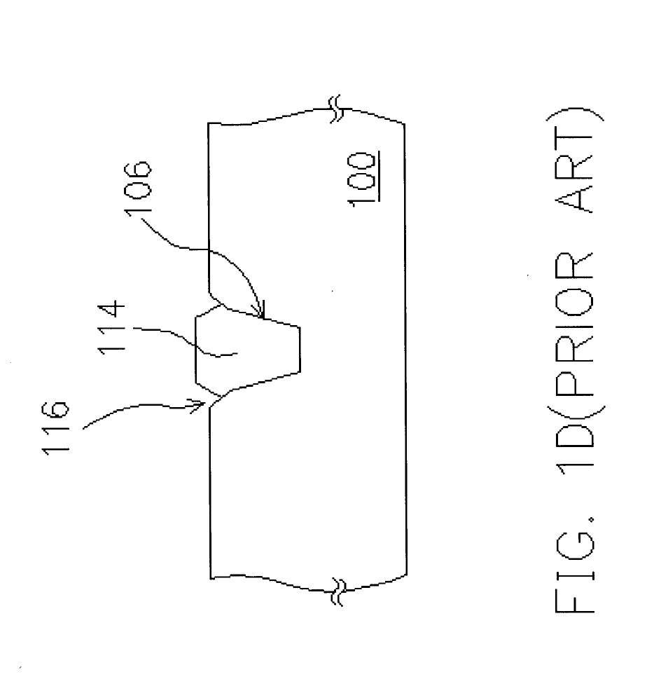

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

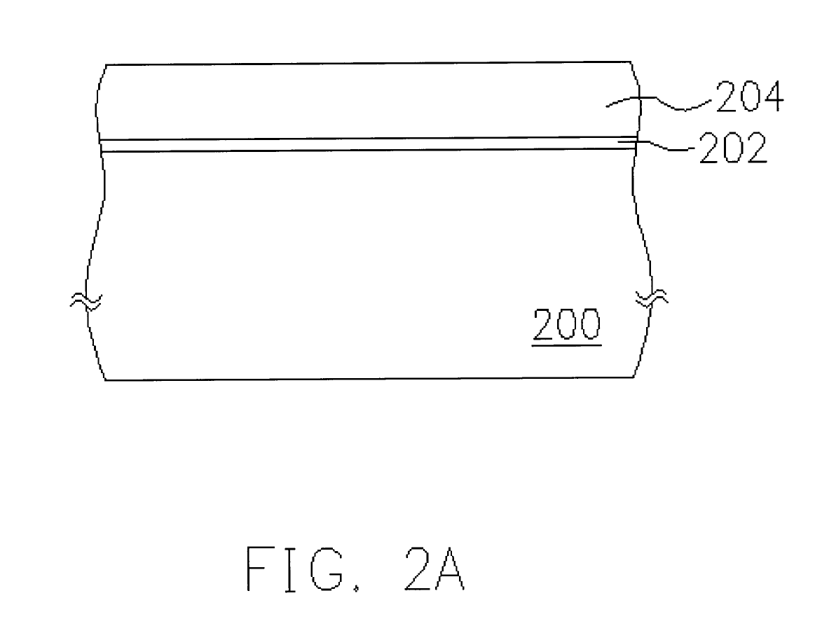

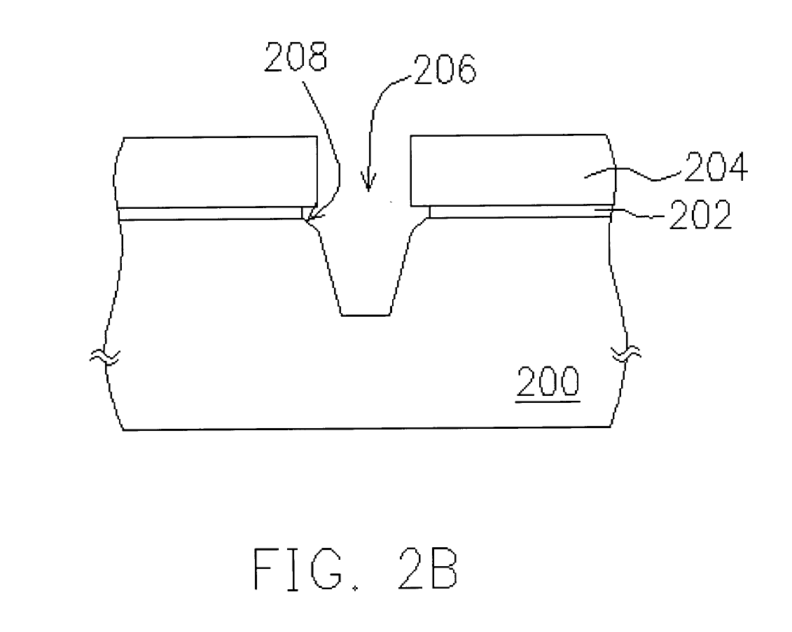

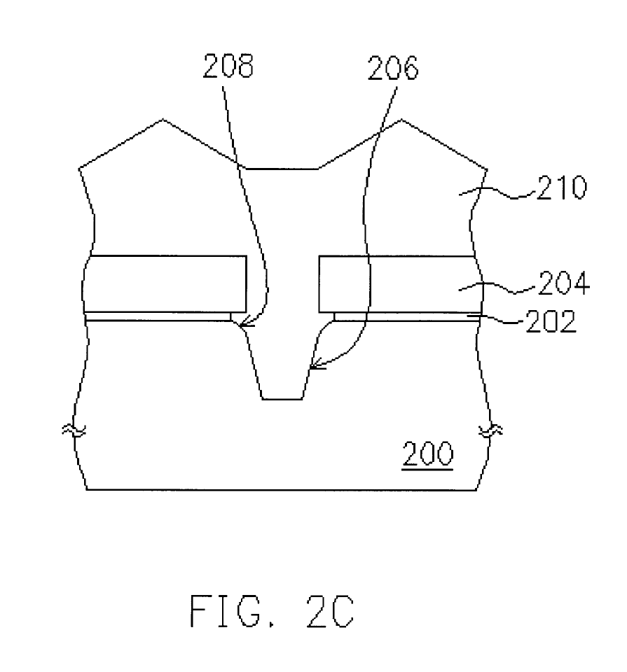

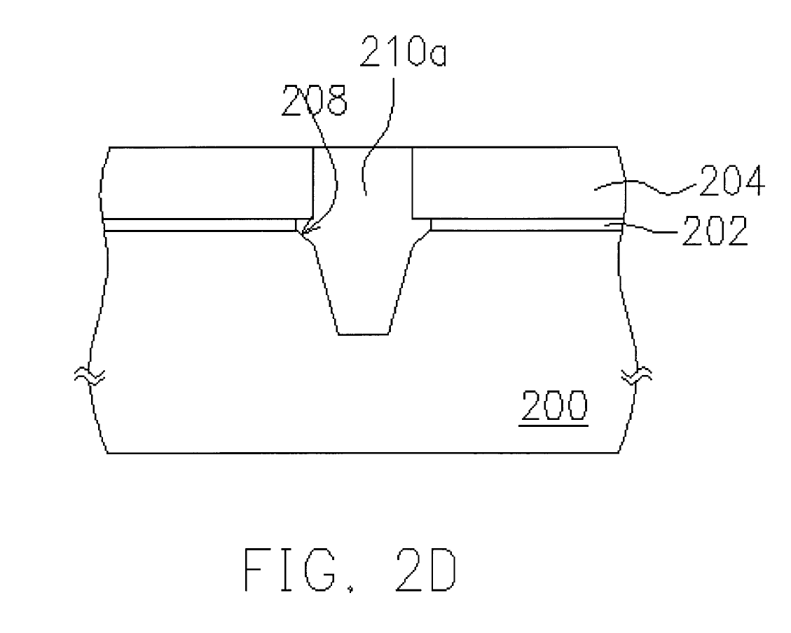

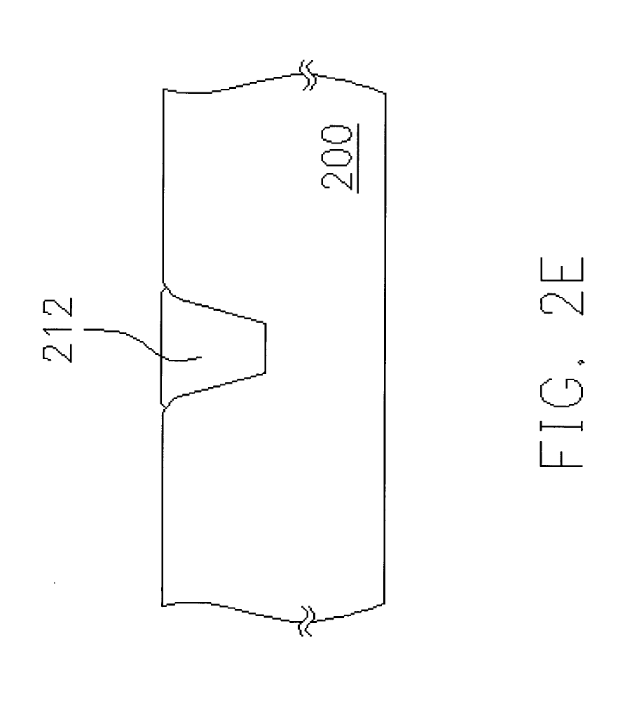

FIGS. 2A through 2E are schematic cross-sectional views showing the progression of steps for forming a shallow trench isolation (STI) structure according to one preferred embodiment of this invention. As shown in FIG. 2A, a substrate 200 is provided. A pad oxide layer 202 is formed over the substrate 202. The pad oxide layer 202 can be a silicon oxide layer formed, for example, by thermal oxidation. A mask layer 204 is formed over the pad oxide layer 202. The mask layer 204 can be a silicon nitride layer formed, for example, by chemical vapor deposition.

As shown in FIG. 2B, a portion of the mask layer 204, the pad oxide layer 202 and the substrate 200 are removed to form a trench 206 in the substrate 200. The trench 206 is formed, for example, by forming a patterned photoresist layer (not shown) over the mask layer 204 and performing an anisotropic etching using the patterned photoresist layer as a mask. After the anisotropic etching, a rounded corner structure 208 is also formed at the upper corner region of the trench 206.

As shown in FIG. 2C, a high-density plasma chemical vapor deposition (HDPCVD) having a high etching/deposition ratio is conducted to form an insulation layer 210 that completely fills the trench 206. The insulation layer 210 can be, for example, a silicon oxide layer. To produce a high etching/deposition ratio for the HDPCVD process, the ratio between silane SiH₄ and oxygen in the gaseous reactive mixture is lowered and the operating power of the high frequency radio frequency (HFRF) is increased, for example. Hence, an etching/deposition ratio of between about 0.15 and 0.6 is achieved. Typically, the HDPCVD process is conducted respectively at a temperature between about 550˜700° C. (preferably about 560˜700° C.), at a low frequency radio frequency (LFRF) power between about 2700 and 4500 W (preferably between about 3310 W and 4500 W), and at a high frequency radio frequency (HFRF) power between about 2700 W and 4000 W (preferably between about 3310 W and 4000 W). The gaseous mixture needed to conduct the HDPCVD is produced by passing silane SiH₄, oxygen and helium. The flow rate of silane SiH₄ is between about 80 sccm and 150 sccm. The flow rate of oxygen is between about 120 sccm and 210 sccm, preferably between about 120 sccm and 195 sccm. The flow rate of helium is between about 180 sccm and 280 sccm.

In the HDPCVD step, the insulation layer 210 is formed at a high etching/deposition ratio. In other words, a HDPCVD process with a higher etching capacity is used. Since any material deposited on the sidewall of the trench 206 is rapidly removed without forming any obstacle items that prevent subsequent deposition, a HDPCVD process operating with a high etching/deposition ratio has exceptional gap-filling capacity and induces a “re-deposition” effect. Ultimately, the trench 206 is completely filled by the insulating material without forming any weak spots.

As shown in FIG. 2D, the insulation material outside the trench 206 is removed to form a plug of oxide material 210a inside the trench 206. Excess insulation material can be removed from the insulation layer 210 by chemical-mechanical polishing (CMP) using the mask layer 240 as a polishing stop layer.

As shown in FIG. 2E, the mask layer 204 and the pad oxide layer are sequentially removed to form a complete STI structure 212. The mask layer 104 can be removed, for example, by immersing the substrate 200 in a bath of hot phosphoric acid in a wet etching operation. The pad oxide layer 102 is removed, for example, by immersing the substrate 200 in a bath of hydrofluoric acid solution in a wet etching operation. Because the insulation layer 210 is able to fill the trench 206 completely without forming any weak spots, no recess cavities are formed after the removal of the mask layer 204 and the pad oxide layer 202. Without any recess cavities on the substrate 200, sources for producing leakage current are eliminated.

In conclusion, one major aspect of this invention is the use of a high etching/deposition ratio in carrying out the HDPCVD process. A high etching/deposition ratio for a HDPCVD process has a high gap-filling capacity. Hence, insulating material can still completely fill the trench without forming any weak spot even if a rounded corner structure is present in the substrate at the upper corner region of the trench.

Since the insulation layer is free of any weak spots, a recess cavity that exposes a portion of the substrate is absent from the STI structure. Hence, damages to the exposed substrate near the recess cavity are prevented.

Finally, the absence of recess cavities around the STI structure also prevents any accumulation of electric charges in the subsequent formation of a gate oxide layer. Ultimately, the source of leakage current is removed and a lowering of threshold voltage for the gate oxide layer is prevented.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A method of forming a shallow trench isolation (STI) structure, comprising:
providing a substrate;
forming a pad oxide layer over the substrate;
forming a mask layer over the pad oxide layer;
patterning the substrate to form a trench in the substrate, wherein upper corners of the trench are rounded;
conducting a high-density plasma chemical vapor deposition to form an insulation layer over the substrate and completely filling the trench, wherein the high-density chemical vapor deposition process uses an etching/deposition ratio of about 0.15 to 0.6;
removing the insulation material outside the trench;
removing the mask layer; and
removing the pad oxide layer to form a complete STI structure.

2. The method of claim 1, wherein the high-density plasma chemical vapor deposition is conducted at a temperature between about 560˜700° C.

3. The method of claim 1, wherein the high-density plasma chemical vapor deposition is conducted using a low frequency radio frequency at an operating power level between about 3310 W and 4500 W.

4. The method of claim 1, wherein the high-density plasma chemical vapor deposition is conducted using a high frequency radio frequency at an operating power level between about 3310 W and 4000 W.

5. The method of claim 1, wherein the high-density plasma chemical vapor deposition is conducted using a mixture of gaseous reactants including silane SiH₄, oxygen and helium.

6. The method of claim 5, wherein the mixture of gaseous reactants is produced by introducing silane SiH₄ at a flow rate of between about 80 sccm and 150 sccm, oxygen at a flow rate of between about 120 sccm and 195 sccm, and helium at a flow rate of between about 180 sccm and 280 sccm.

7. The method of claim 1, wherein the insulation layer includes a silicon oxide layer.

8. A method of forming a shallow trench isolation (STI) structure, comprising:
providing a substrate having a trench therein;
conducting a high-density plasma chemical vapor deposition to form an insulation layer over the substrate and completely filling the trench, wherein the high-density chemical vapor deposition process uses an etching/deposition ratio of about 0.15 to 0.6; and
removing the insulation material outside the trench to form a complete STI structure.

9. The method of claim 8, wherein before conducting the high-density plasma chemical vapor deposition, the upper corners of the trench are rounded.

10. The method of claim 8, wherein the high-density plasma chemical vapor deposition is conducted at a temperature between about 560˜700° C.

11. The method of claim 8, wherein the high-density plasma chemical vapor deposition is conducted using a low frequency radio frequency at an operating power level between about 3310 W and 4500 W.

12. The method of claim 8, wherein the high-density plasma chemical vapor deposition is conducted using a high frequency radio frequency at an operating power level between about 3310 W and 4000 W.

13. The method of claim 8, wherein the high-density plasma chemical vapor deposition is conducted using a mixture of gaseous reactants including silane SiH₄, oxygen and helium.

14. The method of claim 13, wherein the mixture of gaseous reactants is produced by introducing silane SiH₄ at a flow rate of between about 80 sccm and 150 sccm, oxygen at a flow rate between about 120 sccm and 195 sccm and helium at a flow rate between about 180 sccm and 280 sccm.

15. The method of claim 8, wherein the insulation layer includes a silicon oxide layer.
